(19) United States
(12) Patent Application Publication
(10) Pub. No.: US 2016/0078997 A1
(43) Pub. Date: Mar. 17, 2016

(54) INDUCTOR ARRAY CHIP AND BOARD HAVING THE SAME

(71) Applicant: SAMSUNG ELECTRO-MECHANICS CO., LTD., Suwon-Si (KR)

(72) Inventors: Soo Hwan SON, Suwon-Si (KR); Yu Jin CHOI, Suwon-Si (KR); Ho Yoon KIM, Suwon-Si (KR)

(21) Appl. No.: 14/678,912

(22) Filed: Apr. 3, 2015

(30) Foreign Application Priority Data
Sep. 16, 2014 (KR) 10-2014-0122896

(51) Int. Cl. H01F 27/28; H01F 27/29; H05K 1/18

(52) U.S. Cl. CPC H01F 27/2804; H05K 1/181; H01F 27/292; H01F 2027/2809

(57) ABSTRACT

There are provided an inductor array chip and a board having the same. The inductor array chip includes: a body in which a plurality of magnetic layers are stacked; first and second coil parts having a plurality of conductive patterns and a plurality of conductive vias formed in the plurality of magnetic layers; and first to fourth external electrodes disposed on outer surfaces of the body to be connected to both ends of the first and second coil parts, wherein the first and second coil parts are disposed in a thickness direction of the body and are separated from each other by a gap layer disposed therebetween.

### CROSS-REFERENCE TO RELATED APPLICATION

This application claims the priority and benefit of Korean Patent Application No. 10-2014-0122896 filed on Sep. 16, 2014, with the Korean Intellectual Property Office, the disclosure of which is incorporated herein by reference.

### BACKGROUND

The present disclosure relates to an inductor array chip and a board having the same.

An inductor, a multilayer chip component, is a representative passive element configuring an electronic circuit together with a resistor and a capacitor so as to remove noise therefrom.

A multilayer chip type inductor may be manufactured by printing conductive patterns on a magnetic material or a dielectric material so as to form coil patterns and then cutting and stacking the magnetic material or the dielectric material with the coil patterns formed thereon.

Such a multilayer chip inductor has a structure in which a plurality of magnetic layers on which the conductive patterns are formed are stacked, and the internal conductive patterns in the multilayer chip inductor are sequentially connected to each other by via electrodes formed in the respective magnetic layers in order to form a coil structure in the chip, thereby obtaining target characteristics such as inductance, impedance, and the like.

In addition, in accordance with the recent trend for slimness and lightness in electronic devices, there has been increasing demand for the simplification of power inductor structures.

Particularly, user demand for inductors able to be miniaturized while providing excellent performance has increased.

Meanwhile, since inductors have recently been widely used as multiphase devices, or the like, an application of the inductors as an array form has advantages in the light of a decrease in a mounting area as well as a decrease in the number of inductors to be mounted.

However, since the array form has a coupling problem due to a short distance between coils in the same chip, measures for the above-mentioned problem are needed.

### RELATED ART DOCUMENT

(Patent Document 1) Japanese Patent Laid-Open Publication No. 2001-155950

### SUMMARY

An aspect of the present disclosure may provide an inductor array chip and a board having the same.

According to an aspect of the present disclosure, an inductor array chip may include: a body in which a plurality of magnetic layers are stacked; first and second coil parts having a plurality of conductive patterns and a plurality of conductive vias formed in the plurality of magnetic layers; and first to fourth external electrodes disposed on outer surfaces of the body to be connected to both ends of the first and second coil parts, wherein the first and second coil parts are disposed in a thickness direction of the body and are separated from each other by a gap layer disposed therebetween.

According to another aspect of the present disclosure, a board may include: a printed circuit board having a plurality of electrode pads formed on an upper surface thereof; and an inductor array chip mounted on the printed circuit board, wherein the inductor array chip includes a body in which a plurality of magnetic layers are stacked, first and second coil parts having a plurality of conductive patterns and a plurality of conductive vias formed in the plurality of magnetic layers, and first to fourth external electrodes disposed on outer surfaces of the body to be connected to both ends of the first and second coil parts, and the first and second coil parts are disposed in a thickness direction of the body and are separated from each other by a gap layer disposed therebetween.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a perspective view of an inductor array chip according to an exemplary embodiment of the present disclosure;

FIG. 2 is a cross-sectional view taken along the line A-A′ of FIG. 1;

FIG. 3 is an exploded perspective view illustrating a structure of the inductor array chip shown in FIG. 1; and

FIG. 4 is a perspective view of a board in which the inductor array chip of FIG. 1 is mounted on a printed circuit board.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

A direction of a hexahedron will be defined in order to clearly describe exemplary embodiments of the present disclosure. L, W and T shown in the accompanying drawings refer to a length direction, a width direction, and a thickness direction, respectively. Here, the thickness direction may be the same as a stacking direction in which magnetic layers are stacked.

Inductor Array Chip

An inductor array chip according to an exemplary embodiment of the present disclosure may be appropriately used as a chip inductor having conductive patterns formed on magnetic layers, a power inductor, a chip beads, a chip filter, or the like.

Hereinafter, exemplary embodiments of the present disclosure will be described in detail with reference to the accompanying drawings.

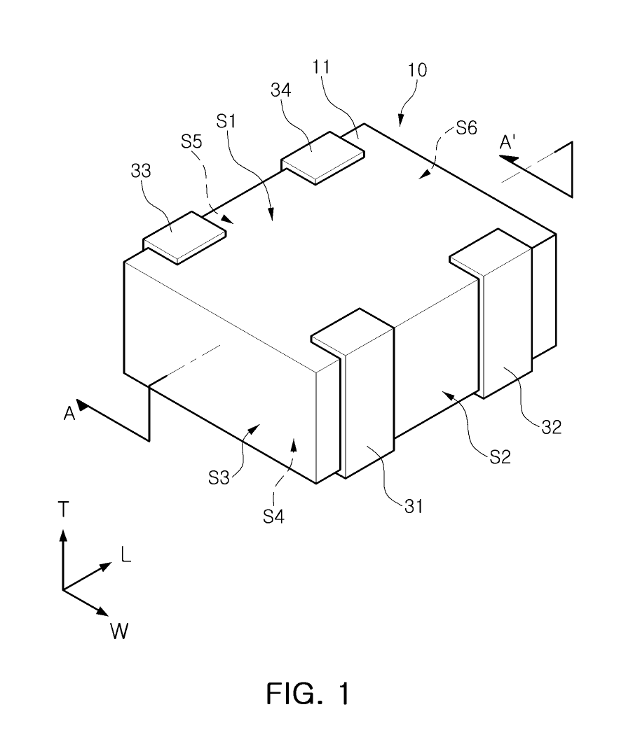

FIG. 1 is a perspective view of an inductor array chip according to an exemplary embodiment of the present disclosure.

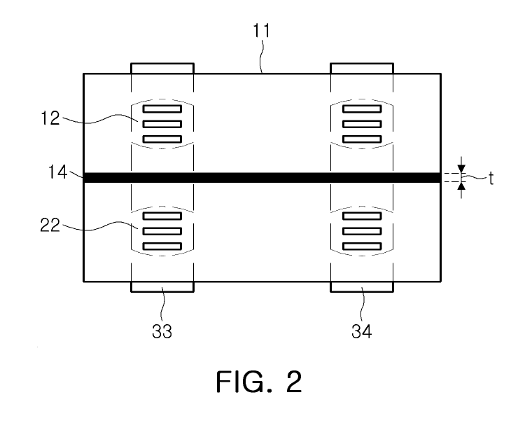

FIG. 2 is a cross-sectional view taken along the line A-A′ of FIG. 1.

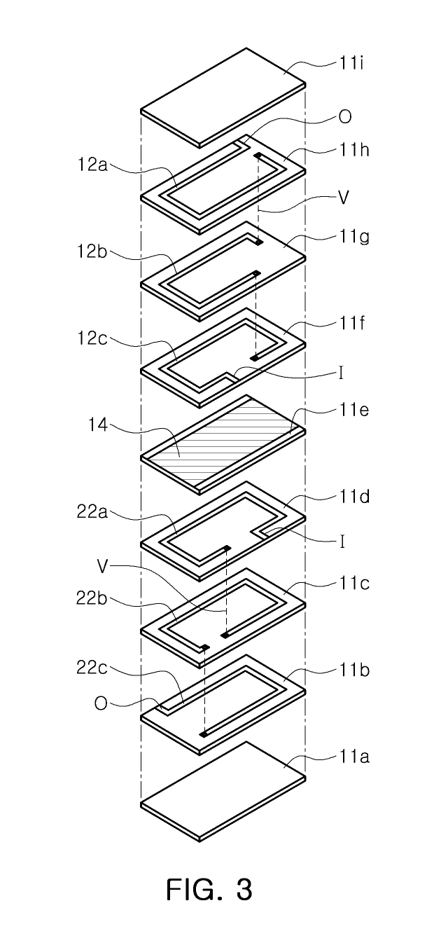

FIG. 3 is an exploded perspective view illustrating a structure of the inductor array chip shown in FIG. 1.

Referring to FIGS. 1 through 3, an inductor array chip according to an exemplary embodiment of the present disclosure may include a body 11 on which a plurality of magnetic layers 11a to 11i are stacked, a plurality of conductive patterns 12a to 12c and 22a to 22c formed on the plurality of magnetic layers 11b to 11d and 11f to 11h, first and second coil parts 12 and 22 having a plurality of conductive vias V, and first to fourth external electrodes 31, 32, 33, and 34 disposed on outer surfaces of the body 11 and connected to both ends of the first and second coil parts 11 and 22, respectively.

In addition, the first and second coil parts 12 and 22 may be disposed in a thickness direction of the body 11 and may be separated from each other by a gap layer 14 disposed therebetween.

The body 11 of the inductor array chip 10 may be formed by stacking the plurality of magnetic layers 11a to 11i, as shown in FIG. 3.

Top and bottom magnetic layers 11a and 11i among the plurality of magnetic layers 11a to 11i may be cover layers and may be configured of only the magnetic layers on which the conductive patterns are not formed.

The cover layers 11a and 11i may be each configured of a plurality of layers depending on a required thickness.

According to the present exemplary embodiment, the magnetic layers 11b to 11d and 11f to 11h except for some magnetic layers 11a and 11i such as the cover layers and the magnetic layer 11e forming the gap layer as described below among the plurality of magnetic layers may be provided with the conductive patterns 12a to 12c and 22a to 22c and the conductive vias V.

The conductive patterns 12a to 12c configuring the first coil part the conductive patterns 22a to 22c configuring the second coil part among the conductive patterns 12a to 12c and 22a to 22c may be respectively connected each other by the conductive vias V so as to form the first coil part 12 and the second coil part 22 wound around an overlapped position.

Both ends I and O of the first coil part 12 may have a form that is led so as to be able to be connected to the first and fourth external electrodes 31 and 34, respectively.

In addition, both ends I and O of the second coil part 22 may have a form that is led so as to be able to be connected to the second and third external electrodes 32 and 33, respectively.

Therefore, the first external electrode 31 and the second external electrode 32 may function as an input terminal, and the third external electrode 33 and the fourth external electrode 34 may function as an output terminal, but are not limited thereto.

The body 11 may be manufactured by printing the conductive patterns 12a to 12c and 22a to 22c on magnetic green sheets, stacking the magnetic green sheets having the conductive patterns 12a to 12c and 22a to 22c formed thereon, and then sintering the stacked magnetic green sheets.

The body 11 may have a hexahedral shape. An appearance of the body 11 may not have a hexahedral shape with a complete straight line due to sintering shrinkage of ceramic powders when the magnetic green sheets are stacked and are then sintered in a chip shape. However, the body 11 may substantially have the hexahedral shape.

The magnetic layers 11a to 11i may be formed of a ferrite or metal based soft magnetism material, but is not necessarily limited thereto.

Examples of the ferrite may include ferrite known in the art such as Mn—Zn based ferrite, Ni—Zn based ferrite, Ni—Zn—Cu based ferrite, Mn—Mg based ferrite, Ba based ferrite, Li based ferrite, or the like.

The metal base soft magnetism material may be an alloy containing at least one selected from a group consisting of Fe, Si, Cr, Al, and Ni. For example, the metal base soft magnetism material may contain Fe—Si—B—Cr based amorphous metal particles, but is not limited thereto.

The metal based soft magnetism material may have a particle diameter 0.1 μm to 30 μm and may be contained in a form in which it is dispersed on a polymer such as an epoxy resin, polyimide, or the like.

Meanwhile, the conductive patterns 12a to 12c and 22a to 22c may be formed by printing a conductive paste containing silver (Ag) as a main component at a predetermined thickness. The conductive patterns 12a to 12c and 22a to 22c may be electrically connected to the first to fourth external electrodes 31, 32, 33, and 34 which are formed at both end portions in a length direction.

The first to fourth external electrodes 31, 32, 33, and 34 may be formed at both end portions in a width direction of the body 11 and may be formed of only nickel (Ni), copper (Cu), tin (Sn), or silver (Ag), or the like, or an alloy thereof, but the material is not limited thereto.

In addition, a method of forming the first to fourth external electrodes 31, 32, 33, and 34 is not limited to a plating method, but the first to fourth external electrodes 31, 32, 33, and 34 may also be formed by applying the conductive paste.

The four conductive patterns 12a, 12c, 22a, and 22c among the conductive patterns 12a to 12c and 22a to 22c may have leads which are electrically connected to the first to fourth external electrodes 31, 32, 33, and 34.

According to an exemplary embodiment of the present disclosure, the conductive patterns 12a to 12c and 22a to 22c each have the number of turns of 2.5, but are not limited thereto.

In order for the respective conductive patterns configuring the first coil part 12 and the second coil part 22 among the conductive patterns to have the number of turns of 2.5, the magnetic layers 11b to 11d and 11f to 11h having the conductive patterns 12a to 12c and 22a to 22c formed thereon may be disposed between the top and bottom magnetic layers 11a and 11i forming the cover layers.

Referring to FIG. 2, the first and second coil parts 12 and 22 may be disposed in the thickness direction of the body 11 and may be separated from each other by the gap layer 14 disposed therebetween.

According to an exemplary embodiment of the present disclosure, the first coil part 12 may configure a first inductor and the second coil part 22 may configure a second inductor.

A first inductor part including the first coil part 12 and a second inductor part including the second coil part 22 may be connected in series with or in parallel to each other.

The first and second coil parts 12 and 22 may be disposed in the thickness direction of the body 11 and may be positioned vertically in the thickness direction of the body 11.

The central cores of the first coil part 12 and the second coil part 22 may be positioned in the same position in the stacked direction of the body 11, but is not necessarily limited thereto.

The central cores of the first coil part 12 and the second coil part 22 may mean a central region of regions of the magnetic layers inside the conductive patterns in the case in which the magnetic layers 11b to 11d and 11f to 11h having the conductive patterns 12a to 12c and 22a to 22c formed thereon are stacked.

Alternately, the central cores of the first coil part 12 and the second coil part 22 may mean a central axis region of the coil part in a length-thickness direction of the body 11.

The gap layer 14 may be disposed between the first coil part 12 and the second coil part 22 of the body 11, and the first coil part 12 and the second coil part 22 may be separated from each other by the gap layer 14.

Since the first coil part 12 and the second coil part 22 are separated from each other by the gap layer 14, the first coil part 12 and the second coil part 22 may be non-coupled type coils.

Since the inductor array chip 10 according to an exemplary embodiment of the present disclosure has two or more coil parts on a single chip while allowing the two or more coil parts to be non-coupled to each other at the same time as described above, the coil parts may be designed to have a coupling coefficient of almost zero.

As a result, since the two or more coil parts are formed on the single chip, the number of mounting times may be decreased and the mounting area may be decreased as compared to the structure according to the related art. In addition to this, since the respective coil parts are independently disposed, the respective coils may be manufactured to be large, which results in a structural advantage as compared to a case of two small chips.

The first coil part 12 and the second coil part 22 may have a symmetrical shape based on the gap layer 14 disposed in the body.

The gap layer 14 may include a Zn-ferrite based non-magnetic material having low permeability or a dielectric material including at least one of SiO₂, Al₂O₃, TiO₂, and ZrO₂, but is not necessarily limited thereto.

The gap layer 14 may have a thickness tg of 5 μm or more, while the thickness tg of the gap layer 14 may be equal to or less than half of the thickness of the first or second coil part.

By adjusting the thickness tg of the gap layer 14 to be 5 μm or more, while being equal to or less than half of the thickness of the first or second coil part, the first coil part 12 and the second coil part 22 may be designed to have a coupling coefficient of almost zero therebetween and may be the non-coupled type coil.

In the case in which the thickness tg of the gap layer 14 is less than 5 μm, since magnetic fluxes of the first coil part 12 and the second coil part 22 may affect each other, a coupling between the two coils may become large, and consequently, the non-coupled type product may not be formed.

In addition, the thickness tg of the gap layer 14 exceeds half of the thickness of the first or second coil part 12 and 22, the thickness tg of the gap layer 14 may become too large, and consequently, target inductance may not be obtained.

According to an exemplary embodiment of the present disclosure, the first coil part 12 and the second coil part 22 may have the same direction of rotation. Meanwhile, the first coil part 12 and the second coil part 22 may also have opposite directions of rotation.

In the case in which the first coil part 12 and the second coil part 22 have the same direction of rotation, magnetic flux directions are the same as each other, and in the case in which the first coil part 12 and the second coil part 22 have the opposite directions of rotation, the magnetic flux directions may be formed to be opposite to each other and the first coil part 12 and the second coil part 22 may be non-coupled coils so as not to affect each other.

Board Having Inductor Array Chip

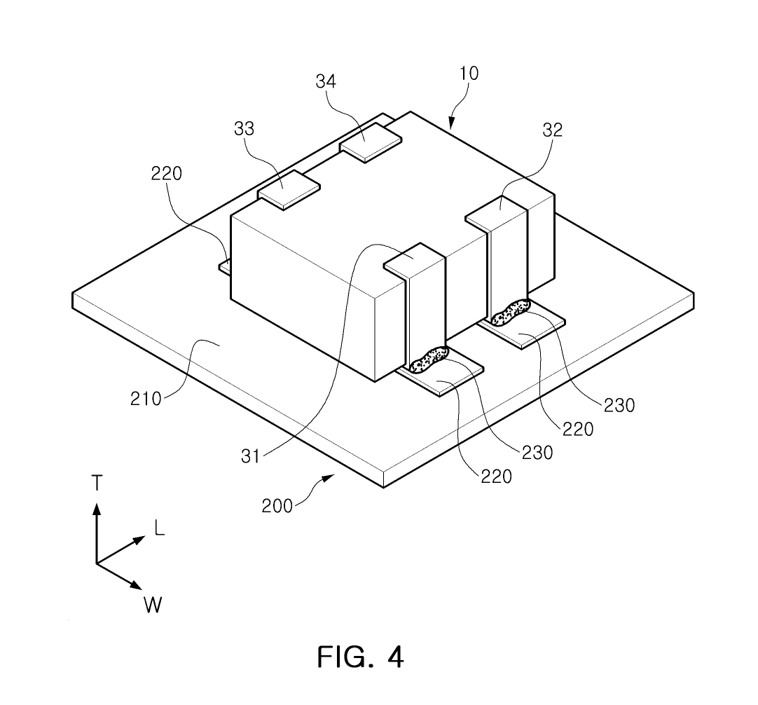

FIG. 4 is a perspective view of a board in which the inductor array chip of FIG. 1 is mounted on a printed circuit board.

Referring to FIG. 4, a board 200 having an inductor array chip 10 according to the present exemplary embodiment may include a printed circuit board 210 on which the inductor array chip 10 is mounted to be horizontal, and a plurality of electrode pads 220 formed on an upper surface of the printed circuit board 210 so as to be spaced apart from each other.

In this case, the inductor array chip 10 may be electrically connected to the printed circuit board 210 by a solder 230 in a state in which the first to fourth external electrodes 31, 32, 33 and 34 are each disposed on the plurality of electrode pads 220 so as to be in contact with each other.

The first coil part 12 and the second coil part 22 may have a symmetrical shape based on the gap layer 14 disposed in the body.

The central cores of the first coil part 12 and the second coil part 22 may be positioned in the same position in the stacked direction of the body 11.

The first coil part 12 and the second coil part 22 may have the same direction of rotation or the opposite directions of rotation.

The gap layer 14 may include a Zn-ferrite based non-magnetic material having low permeability or a dielectric material including at least one of SiO₂, Al₂O₃, TiO₂, and ZrO₂.

The first coil part 12 and the second coil part 22 may be non-coupled type coils.

The first and second external electrodes 31 and 32 may be input terminals and the third and fourth external electrodes 33 and 34 may be output terminals.

Since the inductor array chip 10 according to an exemplary embodiment of the present disclosure and the board 200 having the same allow the two or more coil parts to be formed on the single chip while allowing the two or more coil parts to be non-coupled to each other at the same time as described above, the coil parts may be designed to have the coupling coefficient of almost zero.

As a result, since the two or more coil parts are formed on the single chip, the number of mounting times may be decreased and the mounting area may be decreased as compared to the structure according to the related art. In addition to this, since the respective coil parts are independently disposed, the respective coils may be manufactured to be large, which results in a structural advantage as compared to a case of two small chips.

As set forth above, according to exemplary embodiments of the present disclosure, since the inductor array chip has two or more coil parts on the single chip while allowing the two or more coil parts to be non-coupled to each other at the same time, the coil parts may be designed to have the coupling coefficient of almost zero.

As a result, since the number of mounting times is decreased, the mounting area is decreased, and the respective coil parts are independently disposed, as compared to the structure according to the related art, the respective coils may be manufactured to be large, which results in a structural advantage as compared to the case of two small chips.

While exemplary embodiments have been shown and described above, it will be apparent to those skilled in the art that modifications and variations could be made without departing from the scope of the present invention as defined by the appended claims.

What is claimed is:

1. An inductor array chip comprising:
a body in which a plurality of magnetic layers are stacked;
first and second coil parts having a plurality of conductive patterns and a plurality of conductive vias disposed in the plurality of magnetic layers; and
first to fourth external electrodes disposed on outer surfaces of the body to be connected to both ends of the first and second coil parts,
wherein the first and second coil parts are disposed in a thickness direction of the body and are separated from each other by a gap layer disposed therebetween.

2. The inductor array chip of claim 1, wherein the first coil part and the second coil part are symmetrical with respect to each other on the basis of the gap layer disposed in the body.

3. The inductor array chip of claim 1, wherein the gap layer has a thickness of 5 μm or more while the thickness of the gap layer is equal to or less than half of a thickness of the first or second coil part.

4. The inductor array chip of claim 1, wherein the first coil part and the second coil part have respective central cores positioned in the same position in a stacking direction of the body.

5. The inductor array chip of claim 1, wherein the first coil part and the second coil part have the same direction of rotation.

6. The inductor array chip of claim 1, wherein the first coil part and the second coil part have opposing directions of rotation.

7. The inductor array chip of claim 1, wherein the gap layer includes a Zn-ferrite based non-magnetic material having low permeability or a dielectric material, including at least one of SiO₂, Al₂O₂, TiO₂, and ZrO₂.

8. The inductor array chip of claim 1, wherein the first coil part and the second coil part are non-coupled type coils.

9. The inductor array chip of claim 1, wherein the first and second external electrodes are input terminals, and the third and fourth external electrodes are output terminals.

10. A board having an inductor array chip, the board comprising:
a printed circuit board on which a plurality of electrode pads are provided; and
an inductor array chip mounted on the printed circuit board,
wherein the inductor array chip includes a body in which a plurality of magnetic layers are stacked, first and second coil parts having a plurality of conductive patterns and a plurality of conductive vias provided in the plurality of magnetic layers, and first to fourth external electrodes disposed on outer surfaces of the body to be connected to both ends of the first and second coil parts, and
the first and second coil parts are disposed in a thickness direction of the body and are separated from each other by a gap layer disposed therebetween.

11. The board of claim 10, wherein the first coil part and the second coil part are symmetrical with respect to each other on the basis of the gap layer disposed in the body.

12. The board of claim 10, wherein the gap layer has a thickness of 5 μm or more while the thickness of the gap layer is equal to or less than half of a thickness of the first or second coil part.

13. The board of claim 10, wherein the first coil part and the second coil part have respective central cores positioned in the same position in a stacking direction of the body.

14. The board of claim 10, wherein the first coil part and the second coil part have the same direction of rotation.

15. The board of claim 10, wherein the first coil part and the second coil part have opposite directions of rotation.

16. The board of claim 10, wherein the gap layer includes a Zn-ferrite based non-magnetic material having low permeability or a dielectric material including at least one of SiO₂, Al₂O₃, TiO₂, and ZrO₂.

17. The board of claim 10, wherein the first coil part and the second coil part are non-coupled type coils.

18. The board of claim 10, wherein the first and second external electrodes are input terminals, and the third and fourth external electrodes are output terminals.
